(19) United States
(12) Patent Application Publication
(10) Pub. No.: US 2025/0256660 A1
(43) Pub. Date: Aug. 14, 2025

(54) Seat Device for a Motor Vehicle, Arrangement and Method

(71) Applicant: Mercedes-Benz Group AG, Stuttgart (DE)

(72) Inventor: Dirk STEFFENS, Weinstadt (DE)

(21) Appl. No.: 18/881,195

(22) PCT Filed: Jun. 15, 2023
(86) PCT No.: PCT/EP2023/066127

§ 371 Date: Jan. 3, 2025

(30) Foreign Application Priority Data
Jul. 5, 2022 (DE) 10 2022 002 458.6

(51) Int. Cl. B60R 11/02; B60N 2/64; H05K 5/00; H05K 5/02

(52) U.S. Cl. CPC B60R 11/0235; B60N 2/64; H05K 5/0018; H05K 5/0217; B60R 2011/0276

(57) ABSTRACT

A seat device for a motor vehicle includes a backrest with a display device on a rear side of the backrest for a person sitting behind the seat device. The display device is pivotable by a pivoting device from an inoperative position into an operating position for viewing by the person. The display device is pivotable from the inoperative position into the operating position and from the operating position into the inoperative position by a voice input device depending on a respective input by the person.

### BACKGROUND AND SUMMARY OF THE INVENTION

The invention relates to a seat device for a motor vehicle having at least one backrest. The invention further relates to an arrangement and to a method.

Seat devices are already known from the prior art which can be designed for example as a driver's seat or as a passenger seat., A corresponding display device can be formed, for example in the form of a display or screen, on a backrest of this seat device, so that people who are located behind the seat device, in particular in a rear compartment of the motor vehicle, can accordingly see entertainment information via the display device. Display devices are also known which can display corresponding content from a headliner of the motor vehicle for the people in the rear compartment. Both the display devices on the backrests as well as the display devices from the headliner cannot be stowed away and thus can disturb and affect the person in the rear compartment.

DE 10 2004 009 309 A1 discloses a seat which has a screen on the rear side of its backrest, which screen can be pivoted upwards from an inoperative position, in which the viewing surface of the screen is protected facing towards the backrest, by approx. 180 degrees into an operative position, in which the viewing surface is facing towards a viewer located behind the seat. DE 20 2004 000 292 U1 also shows a flat screen (20) which glides completely into the seat back (10). A drive unit pushes it upwards through a slit (18) into its completely exposed position (20.4) or back down again into its lowest position (20.1).

A method for controlling a seat system is presented in DE 10 2020 207 522 A1. A physiological state of the seat occupant can be assessed based on at least two from heart rate, respiratory rate and heart rate variability. A countermeasure can be carried out, in order to change the physiological state of the seat occupant, and/or data related to the heart rate, respiratory rate and/or heart rate variability can be transmitted.

The object of the present invention is to create a seat device, an arrangement and a method, by means of which an improved and particularly conveniently operated display of content can be realized for a person.

One aspect of invention relates to a seat device for a motor vehicle having at least one backrest, wherein the backrest has at least one display device for a person sitting behind the seat device on a rear side of the backrest.

It is provided that the display device can be displaced and/or pivoted by means of a slide and/or pivoting device from an inoperative position into an operating position for viewing by the person.

In particular, the display device is thus arranged moveably on the backrest and can be adapted in the inoperative position in particular visually to the backrest, whereby it can be provided that it visually looks like a backrest in the inoperative position. In particular, the display device does not affect the view of the person in the inoperative position. In the operating position, the display device has a corresponding display side, wherein content, in particular in the form of films or games, for example, can be displayed on the display side. However, navigation information or similar can also be displayed on the display side.

In particular, the display device is embedded into the internal structure of the seat device, which is designed in particular as a driver's seat and/or as a passenger seat. In the inoperative position, the display device is, or a plurality of display devices that may be installed there are, invisible to the person and covered by a rear seat cover, in particular in a vertical arrangement, in the respective front seat. The cover blends in in particular with the interior or seat design of the seat device. When used, i.e., in the operating position, the display is again unfolded or extended so that the display device can be arranged in a sliding and rotational movement via the pivoting device.

This ensures that in the inoperative position, the display device does not affect or interrupt the unobstructed view of the person and thus also does not detract from the interior design, for example. Therefore, an improved view for passengers in the rear compartment can also be realized.

The seat device has an input device and the input device is designed to pivot the display device from the inoperative position into the operating position or vice versa, depending on a respective input by the person. This makes it possible for the person to pivot the display device in the rear compartment depending on the person or user. Therefore, the person is conveniently able to pivot the display devices from the inoperative position into the operating position or vice versa.

The input device is designed as a voice input device for detecting a voice command by the person. For example, the display device can then be brought out of the inoperative position into the operating position based on a voice command. Therefore, pivoting the display device can be realized extremely conveniently.

According to an advantageous embodiment, in the inoperative position, a display side of the display device is covered for the person. In particular, the display side can have a rear side, which in turn is then designed in the form or style of the rear side of the backrest, whereby it visually looks like the backrest or back side for the person.

It has also proven to be advantageous when the pivoting device has a rail system for sliding and/or pivoting the display device. In particular, the rail system can provide a sliding or rotational movement, so that the display device can be reliably pivoted from the inoperative position into the operating position.

In a further advantageous embodiment, the operating position is adjusted to a different position depending on an inclination of the backrest. In particular, the inclination of the backrest can be detected and the operating position can be adjusted accordingly depending on a respective inclination of the backrest, so that the person can improve their view. Depending on how the inclination is adjusted, an accordingly improved view for the person can be realized on the display device. In particular, the position change can be adjusted automatically depending on the inclination. Thus, control of the inclination of the backrest can be realized.

According to a further advantageous embodiment, the pivoting device is designed for pivoting the display device horizontally and/or vertically. In particular, both horizontal pivoting as well as vertical pivoting can thus be realized. Preferably, horizontal and vertical pivoting can be realized. For example, the position can then be adjusted accordingly depending on the person's wishes, and pivoting can be realized. Furthermore, this also makes it possible for the display device to be completely brought together with the display device of the neighbouring seat by a neighbouring seat device, so that a substantially shared screen or a shared display device can be provided.

A further aspect of the invention relates to an arrangement for a motor vehicle having at least two seat devices according to the preceding aspect.

In an advantageous embodiment of the arrangement, a first display device of a first seat device of the two seat devices and a second display device of a second seat device of the two seat devices can be pivoted in such a way that the first display device and the second display device form a common display surface. In particular, an electronic computing device can be provided for this purpose, which can detect the pivoting of the two display devices accordingly and, when the two display devices are merged, it recognizes that these two are merged and then, for example, in turn determines and displays the corresponding display as a common display. In particular, two display devices can thus be connected and arranged to form one “large overall screen”.

A further aspect of the invention relates to a motor vehicle having at least one seat device according to the preceding aspect or having an arrangement according to the preceding aspect.

The invention also relates to a method for operating a seat device for a motor vehicle having at least one backrest, wherein the backrest has at least one display device for a person sitting behind the seat device on a rear side of the backrest.

In this case, it is provided that the display device can be pivoted by means of a pivoting device from an inoperative position into an operating position for viewing by the person or vice versa.

Advantageous embodiments of the seat device are to be considered as advantageous embodiments of the arrangement and of the method. The seat device and the arrangement have in particular representational features in order to be able to carry out corresponding method steps.

Further advantages, features and details of the invention can be seen from the following description of preferred exemplary embodiments and from the drawings. The features and combinations of features mentioned above in the description as well as the features and combinations of features mentioned below in the description of the figures and/or shown alone in the figures can be used not only in the combination indicated in each case, but also in other combinations or on their own, without leaving the scope of the invention.

### BRIEF DESCRIPTION OF THE DRAWINGS

FIG. 1 shows a schematic plan view of an embodiment of an arrangement; and

FIG. 2 shows a further schematic plan view of an embodiment of an arrangement.

### DETAILED DESCRIPTION OF THE DRAWINGS

In the figures, identical or functionally identical elements are provided with the same reference signs.

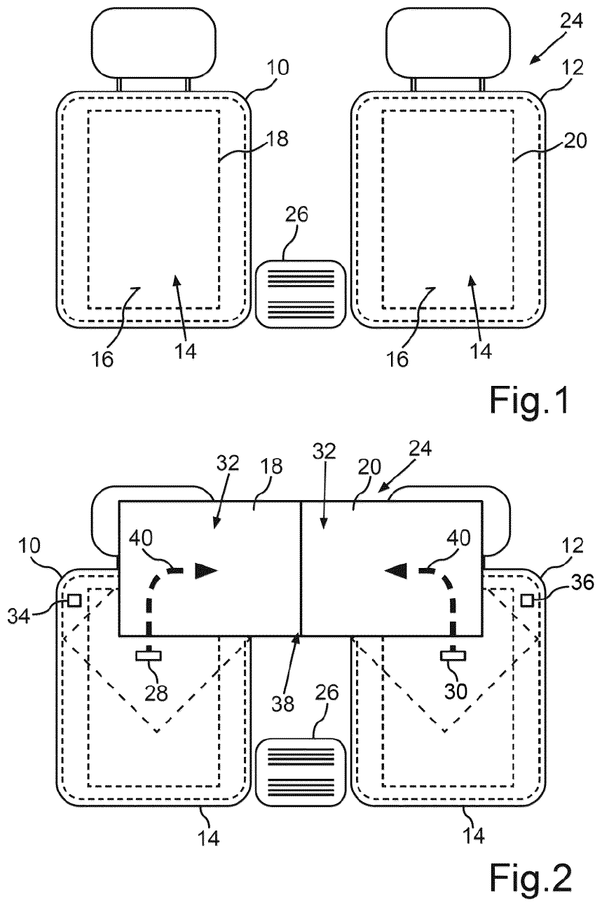

FIG. 1 shows a schematic view of an embodiment of a seat device 10. In the present exemplary embodiment, in particular a first seat device 10, a second seat device 12 and a center console 26 arranged therebetween are shown. The first seat device 10 is a driver's seat, for example, and the second seat device 12 is a passenger seat, for example. In particular, a backrest 14 of the respective seat devices 10, 12 is shown. In particular, FIG. 1 shows the seat devices 10, 12 from the line of sight of a person seated behind the seat devices 10, 12, whereby in particular a rear side 16 of the backrest 14 is represented. For example, the person can be located in the one rear compartment of the motor vehicle.

The seat device 10, 12 has a display device 18, 20 in the present exemplary embodiment. It is shown, in particular, that the first seat device 10 can have a first display device 18 and the second seat device 12 can have a second display device 20. In the present exemplary embodiment, the respective display devices 18, 20 are located in a so-called inoperative position, wherein these are integrated in particular in the backrest 14 and in particular form a single visual front with the backrest 14. In particular, the inoperative position of the respective display devices 18, 20 is thus shown.

The first seat device 10 and the second seat device 12 form an arrangement 24 in the present exemplary embodiment.

FIG. 2 shows a further schematic view of the arrangement 24 and the two seat devices 10, 12. In the present exemplary embodiment, it is in particular shown that the seat devices 10, 12 have a respective pivoting device 28, 30, wherein the display devices 18, 20 can be pivoted into a respective operating position 32 by means of the pivoting devices 28, 30.

In particular, the respective pivoting device 28, 30, in particular a first pivoting device 28 of the first seat device 10 and a second pivoting device 30 of the second seat device 12, is designed as a rail system for pivoting the display devices 18, 20. In particular, horizontal and/or vertical pivoting of the display devices 18, 20 can be carried out by means of the pivoting devices 28, 30.

It can also be provided that a respective seat device 10, 12 has a respective input device 34, 36. The input device 34, 36 can be designed in the form of a key, so that a person can bring the display devices 18, 20 out from the inoperative position into the operating position 32. Alternatively or additionally, the input device 34, 36 can therefore be designed as a first input device 34 and a second input device 36, also in the armrest of the corresponding rear door and similarly as a voice input device, and can carry out the pivoting of the display devices 18, 20 based on a voice command.

FIG. 2 also shows that the arrangement (24) can be provided in such a way that the first display device 18 and the second display device 20 can be pivoted in such a way that the first display device 18 and the second display device 20 form a common display surface 38.

In particular, it is thus provided that the display devices 18, 20 are embedded into the interior structure of the driver's and/or passenger seat. In the inoperative position, the display devices 18, 20 are invisible for the person, in particular in the rear compartment, and covered by the rear seat cover, in particular in a vertical arrangement, in the respective front seat. The cover blends in with the interior or seat design. In the operating position 32, the cover is folded out or extended so that the display devices 18, 20 can be arranged in a sliding and rotational movement 40 via an integrated rail system and can be brought into the operating position 32. Two corresponding display devices 18, 20 can be connected and arranged to form one large overall screen. The control of the extending mechanism can take place via voice control or by keystroke. If necessary, different inclinations of the seat devices 10, 12 can be balanced by adjusting the extension rails in the vehicle longitudinal direction on the one hand and the screen inclination on the other hand, or can be automatically balanced out by a control device.

In particular, the arrangement 24 provides the advantage that in the inoperative position, the display devices 18, 20 do not interrupt the unobstructed view of the persons and the interior design. The two display devices 18, 20 can be arranged to form one large overall screen and thus enlarge the possible screen surface. Therefore, a very good view for the passengers in the rear compartment can be realized. The display devices 18, 20 can be arranged and extended freely by a flexible rail system—also separately from each other, so that for example one person on the left does not use a screen and only one passenger on the right extends the corresponding screen. In particular, simple operation can take place via voice control or keystroke. Furthermore, good integration into the front seat is made possible.

1.-8. (canceled)

9. A seat device for a motor vehicle, comprising:
a backrest, wherein the backrest has a display device on a rear side of the backrest for a person sitting behind the seat device, wherein the display device is pivotable by a pivoting device from an inoperative position into an operating position for viewing by the person; and
an input device, wherein the display device is pivotable from the inoperative position into the operating position and from the operating position into the inoperative position by the input device depending on a respective input by the person and wherein the input device is a voice input device.

10. The seat device according to claim 9, wherein in the inoperative position a display side of the display device is covered.

11. The seat device according to claim 9, wherein the pivoting device has a rail system for pivoting the display device.

12. The seat device according to claim 9, wherein the operating position is adjustable to a different position depending on an inclination of the backrest.

13. The seat device according to claim 9, wherein the display device is horizontally pivotable and/or vertically pivotable by the pivoting device.

14. An arrangement for a motor vehicle, comprising:
a first seat device according to claim 9; and
a second seat device according to claim 9.

15. The arrangement according to claim 14, wherein the first display device of the first seat device and the second display device of the second seat device are pivotable such that the first display device and the second display device form a common display surface.

16. A method for operating a seat device of a motor vehicle, wherein the seat device has a backrest with a display device on a rear side of the backrest for a person sitting behind the seat device, comprising the step of:
pivoting the display device by a pivoting device from an inoperative position into an operating position for viewing by the person.
